(19) United States
(12) Patent Application Publication
(10) Pub. No.: US 2015/0325790 A1
(43) Pub. Date: Nov. 12, 2015

(54) METHOD FOR FORMING RESISTIVE RANDOM ACCESS MEMORY CELL

(71) Applicant: TSINGHUA UNIVERSITY, Haidian District, Beijing (CN)

(72) Inventors: HUAQIANG WU, Beijing (CN); XINYI LI, Beijing (CN); HE QIAN, Beijing (CN)

(21) Appl. No.: 14/655,299

(22) PCT Filed: Dec. 25, 2013
(86) PCT No.: PCT/CN2013/090442

§ 371 Date: Jun. 24, 2015

(30) Foreign Application Priority Data
Dec. 25, 2012 (CN) 201210572687.7

(51) Int. Cl. H01L 45/00

(52) U.S. Cl. CPC H01L 45/1625; H01L 45/1233; H01L 45/146; H01L 45/08; H01L 45/1666; H01L 45/1253

(57) ABSTRACT

A method for forming a resistive random access memory is provided. The method comprises: steps of: S1) providing a silicon substrate; S2) forming an isolation layer on the silicon substrate; S3) forming a bottom electrode on the isolation layer; S4) forming a resistive switching material layer on the bottom electrode by magnetron sputtering at room temperature, comprising: S41) forming a first resistive switching layer of TaOₓ on the bottom electrode by magnetron sputtering under a first deposit pressure and in a first atmosphere, in which 0<x<2; and S42) forming a second resistive switching layer of TaO_{y} on the first resistive switching layer by magnetron sputtering under a second deposit pressure and in a second atmosphere, in which 0<y<2.5; S5) forming a top electrode on the resistive switching material layer; and S6) removing the resistive switching materials TaOₓ and TaO_{y} sputtered onto contacts of the bottom electrode in step S4.

### FIELD

The present disclosure relates to a semiconductor manufacture field, and more particularly, to a method for forming a resistive random access memory cell.

### BACKGROUND

Resistive random access memories (RRAM) have tremendous application potential. For this, great efforts have been made to find a RRAM preparation process compatible with the CMOS (complementary metal oxide semiconductor) back-end process so as to realize the mass production of RRAM.

In the prior technologies atomic layer deposition, magnetron sputtering and thermal oxidization have been used to deposit the resistive switching materials. Usually high-temperature annealing is adopted to improve the performances and stability of devices. However, the high temperature processes are not compatible with the CMOS back-end process. Moreover, the front-end circuit may be damaged due to the over-high temperature of the back-end process. Therefore, a solution is proposed by developing a low-temperature deposition process which avoids the high-temperature annealing process and also meets the high performances requirements.

### SUMMARY

Embodiments of the present disclosure seek to solve at least one of the problems existing in the prior technologies to at least some extent.

According to an embodiment of the present disclosure, a method for forming a resistive random access memory cell is provided. The method comprises steps of: S1) providing a silicon substrate; S2) forming an isolation layer on the silicon substrate; S3) forming a bottom electrode on the isolation layer; S4) forming a resistive switching material layer on the bottom electrode by magnetron sputtering at room temperature, comprising: S41) forming a first resistive switching layer of TaOₓ on the bottom electrode by magnetron sputtering under a first deposit pressure and in a first atmosphere, in which 0<x<2; and S42) forming a second resistive switching layer of TaO_{y} on the first resistive switching layer by magnetron sputtering under a second deposit pressure and in a second atmosphere, in which 0<y<2.5; S5) forming a top electrode on the resistive switching material layer; and S6) removing the resistive switching materials TaOₓ and TaO_{y} sputtered onto contacts of the bottom electrode in step S4.

In some embodiments, step S4 is repeated to form a multilayer resistive switching material structure having a plurality of first resistive switching layers and a plurality of second resistive switching layers alternated with one another.

In some embodiments, the first deposit pressure is less than the second deposit pressure. In some embodiments, the first deposit pressure is 10⁻³ T and the second deposit pressure is in a range of 10⁻³ T to 10⁻² T.

In some embodiments, the first atmosphere and the second atmosphere are a gas mixture of oxygen and argon, and a mole percentage of oxygen in the first atmosphere is less than that of oxygen in the second atmosphere.

In some embodiments, the mole percentage of oxygen in the first atmosphere is less than 5% and the mole percentage of oxygen in the second atmosphere is more than 4%.

In some embodiments, a thickness of the first resistive switching layer is greater than that of the second resistive switching layer.

In some embodiments, the thickness of the first resistive switching layer is in a range of 10 nm to 80 nm, and the thickness of the second resistive switching layer is in a range of 5 nm to 20 nm.

In some embodiments, a pattern of the top electrode is formed by lithography. In some embodiments, step S5 further comprises: forming a photoresist on the top electrode;

and etching a portion of the resistive switching material layer uncovered by the top electrode and a portion of the bottom electrode below the portion of the resistive switching material layer until the isolation layer is exposed so as to define a size of the resistive random access memory cell.

In the present disclosure, the resistive random access memory cell comprising double resistive switching layers of TaOₓ and TaO_{y} is fabricated by adjusting the deposit pressure and the oxygen content of the process gas in the process of magnetron sputtering at room temperature. The bottom electrode, the top electrode and the first and second resistive switching layers are formed at room temperature in a magnetron sputtering coating equipment, the bottom and top electrode patterns are formed by lithography, and the size of the resistive random access memory cell is defined by stripping and etching. Only one magnetron sputtering coating equipment is needed to integrate the method for forming the resistive random access memory cell according to the present disclosure with the CMOS back-end process, which reduces the cost and improves the convenience of the integration. The resistive random access memory cell does not involve the high-voltage formation process and has a high endurance, thus not only ensuring the performance and stability of the resistive random access memory cell, but also solving the technology difficulty to develop a low-temperature deposition process that meets the high performance requirements and avoids high-temperature annealing process.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the accompanying drawings, in which:

FIG. 1 is a flow chart of a method for forming a resistive random access memory cell according to an embodiment of the present disclosure;

FIG. 2 is a flow chart of a method for forming a resistive random access memory cell according to another embodiment of the present disclosure; and

FIG. 3 is schematic diagram of a resistive random access memory cell according to an embodiment of the present disclosure.

### DETAILED DESCRIPTION

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

In the specification, unless specified or limited otherwise, relative terms such as “central”, “longitudinal”, “lateral”, “front”, “rear”, “right”, “left”, “inner”, “outer”, “lower”, “upper”, “horizontal”, “vertical”, “above”, “below”, “up”, “top”, “bottom” as well as derivative thereof (e.g., “horizontally”, “downwardly”, “upwardly”, etc.) should be construed to refer to the orientation as then described or as shown in the drawings under discussion. These relative terms are for convenience of description and do not require that the present disclosure be constructed or operated in a particular orientation.

In addition, terms such as “first” and “second” are used herein for purposes of description and are not intended to indicate or imply relative importance or significance. Thus, the feature defined with “first” and “second” may comprise one or more this feature. In the description of the present disclosure, “a plurality of” means two or more than two, unless specified otherwise.

In the description of the present disclosure, it should be understood that, unless specified or limited otherwise, the terms “mounted,” “connected,” and “coupled” and variations thereof are used broadly and encompass such as mechanical or electrical mountings, connections and couplings, also can be inner mountings, connections and couplings of two components, and further can be direct and indirect mountings, connections, and couplings, which can be understood by those skilled in the art according to the particular embodiment of the present disclosure.

In the description of the present disclosure, a structure in which a first feature is “on” a second feature may include an embodiment in which the first feature directly contacts the second feature, and may also include an embodiment in which an additional feature is formed between the first feature and the second feature so that the first feature does not directly contact the second feature, unless specified otherwise. Furthermore, a first feature “on,” “above,” or “on top of” a second feature may include an embodiment in which the first feature is right “on,” “above,” or “on top of” the second feature, and may also include an embodiment in which the first feature is not right “on,” “above,” or “on top of” the second feature, or just means that the first feature is at a height higher than that of the second feature. While a first feature “beneath,” “below,” or “on bottom of” a second feature may include an embodiment in which the first feature is right “beneath,” “below,” or “on bottom of” the second feature, and may also include an embodiment in which the first feature is not right “beneath,” “below,” or “on bottom of” the second feature, or just means that the first feature is at a height lower than that of the second feature.

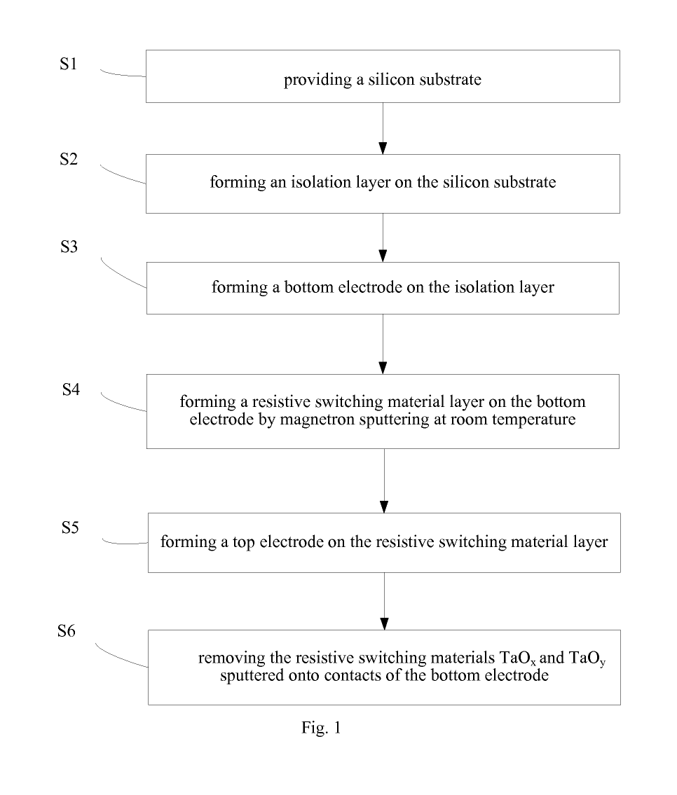

As shown in FIG. 1, according to an embodiment of the present disclosure, a method for forming a resistive random access memory cell is provided. The method comprises the following steps.

Step S1) a silicon substrate is provided.

Specifically, a Si substrate 100 is provided, and there are no special limitations on the crystallographic orientation and crystallographic face indices of the Si substrate 100.

Step S2) an isolation layer is formed on the silicon substrate. Specifically, the silicon dioxide isolation layer 200 may be formed by thermal oxidation.

Step S3) a bottom electrode is formed on the isolation layer. Specifically, a bottom electrode pattern is formed in the silicon substrate 100 having the silicon dioxide isolation layer 200 by lithography, and then Pt is sputtered into the bottom electrode pattern to form a bottom electrode 300. Preferably, a Ti adhesive layer with a thickness of 5 nm can be formed on the isolation layer 200 by magnetron sputtering before the bottom electrode 300 is formed. The Ti adhesive layer is used to enhance the adhesiveness between the Pt bottom electrode 300 and the silicon dioxide isolation layer 200.

Step S4) a resistive switching material layer is formed on the bottom electrode by magnetron sputtering at room temperature.

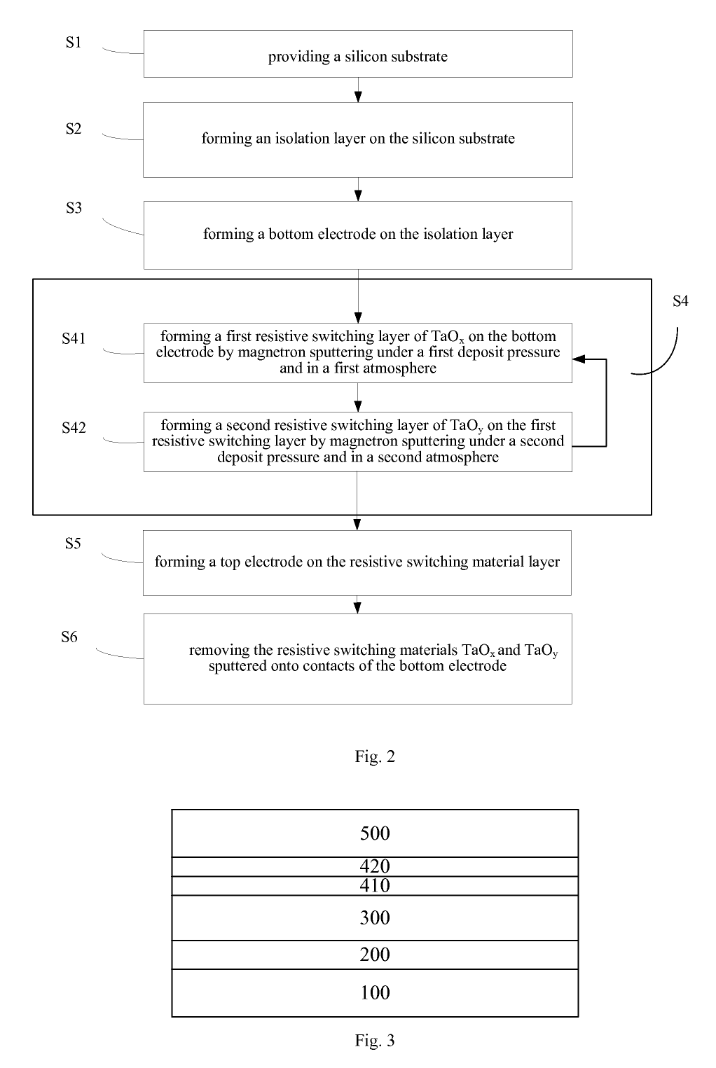

As shown in FIG. 2, step S4 further comprises steps: S41) forming a first resistive switching layer of TaOₓ on the bottom electrode by magnetron sputtering under a first deposit pressure and in a first atmosphere, in which 0<x<2; and S42) forming a second resistive switching layer of

TaO_{y} on the first resistive switching layer by magnetron sputtering under a second deposit pressure and in a second atmosphere, in which 0<y<2.5.

Specifically, under the first deposit pressure of a relatively low value (about 10⁻³T) and in the first atmosphere of a gas mixture of oxygen and argon, in which the oxygen content of the gas mixture is low, e.g., the mole percentage of oxygen is less than 5%, the first resistive switching layer 410 of TaOₓ (0<x<2) with a thickness of more than 10 nm, preferably in a range of 10 nm to 80 nm, is formed by magnetron sputtering. Under the second deposit pressure of a relatively high value (about 10⁻³ T to 10⁻² T) and in the second atmosphere of a gas mixture of oxygen and argon, in which the oxygen content of the gas mixture is high, e.g., the mole percentage of oxygen is more than 4%, the second resistive switching layer 420 of TaO_{y} (0<y<2.5) with a thickness of 5 nm to 20 nm is formed by magnetron sputtering.

Preferably, steps S41 and S42 are performed alternately many times, i.e. adjusting the pressure and component of the process gas, to form a multilayer resistive switching material structure of TaOₓ and TaO_{y}. This multilayer resistive switching material structure can be used in the resistive switching layer of the resistive random access memory cell.

Step S5) a top electrode is formed on the resistive switching material layer.

Specifically, a top electrode pattern is formed by lithography and the size of the resistive random access memory cell is defined, and then Pt is magnetron sputtered into the top electrode pattern to form the top electrode 500.

In some embodiments, step S5 further comprises: forming a photoresist on the top electrode; and etching a portion of the resistive switching material layer uncovered by the top electrode and a portion of the bottom electrode below the portion of the resistive switching material layer until the isolation layer is exposed so as to define the size of the resistive random access memory cell.

Step S6) the resistive switching materials TaOₓ and TaO_{y} sputtered onto contacts of the bottom electrode in step S4 are removed.

Specifically, when the resistive switching materials TaOₓ and TaO_{y} are magnetron sputtered onto a top surface of the bottom electrode 300 in step S4, as the sputtered particles are scattered in all directions, some resistive switching materials are unavoidably formed on the contacts of the bottom electrode 300, i.e. the contacts of the bottom electrode 300 is covered by the resistive switching materials, and the resistive switching materials on the contacts of the bottom electrode 300 need to be removed. Usually, a photoresist is used as a mask, a diluted hydrofluoric acid solution is used to wet etch the tantalum oxides (i.e. TaOₓ and TaO_{y}) on the contacts of the bottom electrode and acetone is used to soak and remove the remaining photoresist.

As shown in FIG. 3, the resistive random access memory cell formed based on the above method according to an embodiment of the present disclosure comprises: a bottom electrode 300, a first resistive switching layer 410 formed on the bottom electrode 300, a second resistive switching layer 420 formed on the first resistive switching layer 410, and a top electrode 500 formed on the second resistive switching layer 420. Moreover, a silicon substrate 100 and a silicon dioxide isolation layer 200 are also shown in FIG. 3.

In the present disclosure, the resistive random access memory cell comprising double resistive switching layers of TaOₓ and TaO_{y} is fabricated by adjusting the deposit pressure and the oxygen content of the process gas in the process of magnetron sputtering at room temperature. The bottom electrode, the top electrode and the first and second resistive switching layers are formed at room temperature in a magnetron sputtering coating equipment, the bottom and top electrode patterns are formed by lithography, and the size of the resistive random access memory cell is defined by stripping and wet etching. Only one magnetron sputtering coating equipment is needed to integrate the method for forming the resistive random access memory cell according to the present disclosure with the CMOS back-end process, which reduces the cost of the integration and improves the convenience of the integration. The resistive random access memory cell does not involve the high-voltage formation process and has a high endurance, thus not only ensuring the performance and stability of the resistive random access memory cell, but also solving the technology difficulty to develop a low-temperature deposition process that meets the high performance requirements and avoids high-temperature annealing process.

It will be understood that, the flow chart or any process or method described herein in other manners may represent a module, segment, or portion of code that comprises one or more executable instructions to implement the specified logic function(s) or that comprises one or more executable instructions of the steps of the progress. Although the flow chart shows a specific order of execution, it is understood that the order of execution may differ from that which is depicted. For example, the order of execution of two or more boxes may be scrambled relative to the order shown.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

What is claimed is:

1. A method for forming a resistive random access memory cell, comprising steps of:
S1) providing a silicon substrate;
S2) forming an isolation layer on the silicon substrate;
S3) forming a bottom electrode on the isolation layer;
S4) forming a resistive switching material layer on the bottom electrode by magnetron sputtering at room temperature, comprising:
S41) forming a first resistive switching layer of TaOₓ on the bottom electrode by magnetron sputtering under a first deposit pressure and in a first atmosphere, in which 0<x<2; and
S42) forming a second resistive switching layer of TaO_{y} on the first resistive switching layer by magnetron sputtering under a second deposit pressure and in a second atmosphere, in which 0<y<2.5;
S5) forming a top electrode on the resistive switching material layer; and
S6) removing the resistive switching materials TaOₓ and TaO_{y} sputtered onto contacts of the bottom electrode in step S4.

2. The method according to claim 1, wherein step S4 is repeated to form a multilayer resistive switching material structure having a plurality of first resistive switching layers and a plurality of second resistive switching layers alternated with one another.

3. The method according to claim 1, wherein the first deposit pressure is less than the second deposit pressure.

4. The method according to claim 3, wherein the first deposit pressure is 10⁻³ T and the second deposit pressure is in a range of 10⁻³ T to 10⁻² T.

5. The method according to claim 1, wherein the first atmosphere and the second atmosphere are a gas mixture of oxygen and argon, and a mole percentage of oxygen in the first atmosphere is less than that of oxygen in the second atmosphere.

6. The method according to claim 5, wherein the mole percentage of oxygen in the first atmosphere is less than 5% and the mole percentage of oxygen in the second atmosphere is more than 4%.

7. The method according to claim 1, wherein a thickness of the first resistive switching layer is greater than that of the second resistive switching layer.

8. The method according to claim 7, wherein the thickness of the first resistive switching layer is in a range of 10 nm to 80 nm, and the thickness of the second resistive switching layer is in a range of 5 nm to 20 nm.

9. The method according to claim 1, wherein a pattern of the top electrode is formed by lithography.

10. The method according to claim 1 or 9, wherein step S5 further comprises:
forming a photoresist on the top electrode; and
etching a portion of the resistive switching material layer uncovered by the top electrode and a portion of the bottom electrode below the portion of the resistive switching material layer until the isolation layer is exposed so as to define a size of the resistive random access memory cell.
